(19) United States
(12) Patent Application Publication
(10) Pub. No.: US 2019/0019439 A1
(43) Pub. Date: Jan. 17, 2019

(54) ADAPTIVE MEDIA AND MOBILITY DEVICE

(71) Applicant: Ryan Oded, New York, NY (US)

(72) Inventor: Ryan Oded, New York, NY (US)

(21) Appl. No.: 15/646,192

(22) Filed: Jul. 11, 2017

(51) Int. Cl. G09F 21/04; H05K 5/00; B62D 63/04; A61G 3/08

(52) U.S. Cl. CPC G09F 21/04; H05K 5/0017; G09F 9/35; A61G 3/0808; B62D 63/04

(57) ABSTRACT

A mobile advertising and mobility conveyance is disclosed in which one or more types of advertising media may be attached to a powered mobile apparatus that may be operated by a user with a physical disability, limited mobility, limited physical dexterity or motor function, or similar condition. Advertising media may include electronic signage such as LED and LCD panels, as well as analog signage such as scrolling and fixed displays. Variants of the conveyance may be adapted for both indoor and outdoor use.

### BACKGROUND

Advertisers are continually looking for a means to distinguish their message from others and to connect with potential customers. On-street marketing remains a popular means for advertisers to connect with consumers, particularly in densely populated areas where slower-moving traffic—pedestrians, cyclists, parents with strollers, vehicles slowed by traffic—afford opportunities to convey messaging in a direct, multifarious, and adaptable manner. A classic example remains the wearable display (also known as the “sandwich board”) in which front and rear panels are connected at least the top and draped over the wearer's shoulders. A fixed message is applied to each of the two panels prior to deployment and the wearer may roam freely, targeting population segments as appropriate, and moving from area to area as needed. The message applied to a wearable display tends to be fixed prior to deployment and cannot be changed during use. Additionally, since the display is entirely supported by the wearer, fatigue and boredom can limit range and effectiveness, and the applicability is largely limited to individuals who are fully ambulatory and possess sufficient physical stamina. Specialized bicycles used for advertising purposes have similar limitations.

Message boards with changeable letters are another common format for on-street advertising. These boards feature a typically rectangular (e.g., 60″×48″) plastic frame, with multiple rows of letters. Individual plastic letters and numbers may slide in from either end to spell out the advertising message, character by character. Many of these boards incorporate wheels to provide mobility from fixed location to fixed location, though the devices are cumbersome and cannot practically be moved around continuously. Changing messages can be a time-consuming process involving changing out the message a single letter at a time, a process that requires manual dexterity. These displays are also typically limited in to characters and very limited graphics, making them rather bland compared to more modern means.

On-street digital signage (LED, LCD, etc.) has become commonplace in urban environments, at bus shelters, trains stations, and even independent kiosks. Many of these locations feature high quality, high-resolution displays that can deliver advertising in a visually arresting manner. However, this signage is fixed in a single location and cannot be moved to more populated areas or take advantage of different locations at different times of the day. Additionally, over time, fixed signage may become yet another element in the visual backdrop of an area and be disregarded by passers-by, no matter what content is displayed.

In many areas, individuals may be utilized to engage pedestrians and solicit business or charitable contribution. In addition to requiring a participant who is fully ambulatory, these methods require licensing in many municipalities, and can be viewed as irritating or invasive by the general public, risking to damage to the underlying brand.

Fixed signage and billboards are similarly ubiquitous, but in addition to being fixed in location and static in content, these billboards tend to blend into the background of an urban environment and have limited effectiveness.

A similar concern is present in many indoor environments such as shopping malls, sporting venues, transportation hubs, and college and university campuses, to name a few. A densely populated area with a particular demographic may be desirable to advertisers who are looking for a way to distinguish their message from a crowded field. Existing electronic signage and media limits the effectiveness of additional signage and media, as “one more” advertisement blends into a backdrop of video, text, colors, and sounds.

Where mobile advertising has been employed in the past, the devices—such as wearable displays, bicycles, moveable signage, etc.—are generally limited and make little or no accommodation for the disabled. The U.S. Centers for Disease Control and Prevention estimates that over 50 million Americans live with a disability of some sort, or more than one in five people in the U.S. alone. See https://www.cdc.gov/media/releases/2015/p0730-us-disability.html. According to the 2015 report, the most common type of disability was a “mobility limitation,” defined as “serious difficulty walking or climbing stairs,” which was reported by one in eight adults. Worldwide, the population experiencing some form of disability is estimated to be 15%, one-fifth of which experience “significant” disabilities. See http://www.worldbank.org/en/topic/disability/overview. Providing accommodation to this population segment taps a vast pool of potential workers. In addition to additional talent, accommodation for the disabled is consistent with the values of many companies, and may also permit a company to take advantage of government incentives such as grants or tax credits.

What is thus needed is an advertising system that is mobile and can be deployed where most effective, on short notice.

What is further needed is a mobile advertising system that is adaptive and accommodates operators with physical disabilities.

What is further needed is a mobile advertising system that is visually engaging to the public.

What us further needed is a mobile advertising system that enables rapid changing of the advertising message.

### SUMMARY

In embodiments, a mobile media conveyance comprises a plurality of frame segments defining a support structure, and at least one media frame, a chassis connected to the support structure comprising a moveable platform, and one or more wheel assemblies, a control panel comprising a control mechanism for directing the movement and direction of the conveyance, at least one media module configured to provide content in response to operator input, and a mobile power source, which may be a rechargeable lithium ion battery array, configured to provide power to the one or more wheel assemblies to drive the movement of the conveyance.

In embodiments, the content may be dynamic, and may be adjusted based upon the location of the conveyance. In embodiments, the at least one of the media frame may be horizontally or vertically slideable. In other embodiments, the connection between the chassis and support structure may be removable. In other embodiments, the media module may be a light emitting diode display, a liquid crystal display, a fixed display, or a scrolling analog display. In embodiments, the control panel may receive direction from an operate in a remote location. In further embodiments, the conveyance is sized in accordance with governmental regulations for the disabled.

In embodiments of the invention, a method of providing mobile advertising comprising is disclosed including providing a mobile advertising conveyance comprising: (a) plurality of frame segments defining a support structure, and at least one media frame; (b) a chassis connected to the support structure comprising one or more wheel assemblies; (c) a control panel; (d) at least one media module in the at least one media frame, wherein the at least one media module is configured to provide content in response to operator input; and (e) a mobile power source configured to provide power to the one or more wheel assemblies to drive the movement of the conveyance. The method may further include the steps of initiating the power source and media module, loading media content on the at least one media module, and causing the conveyance to move forwardly or rearwardly relative to at least one viewer.

### BRIEF DESCRIPTION OF THE DRAWINGS

The features and advantages of the present disclosure will be more fully understood with reference to the following detailed description when taken in conjunction with the accompanying figures, wherein:

FIGS. 1a-1b depict a conveyance according to a preferred embodiment of the invention.

FIG. 2 shows a prototype of a conveyance in use according to embodiments of the invention.

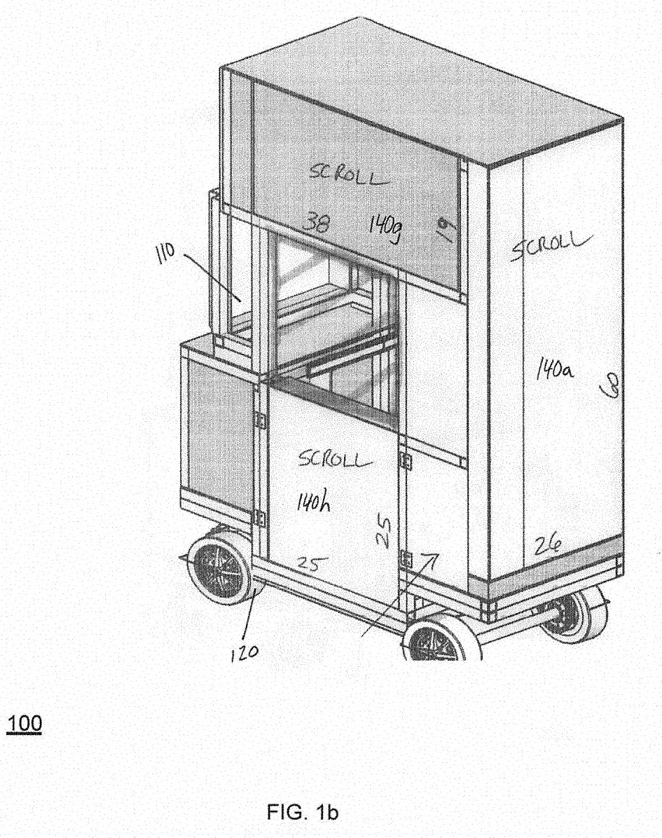

FIG. 3 shows a frame structure according to embodiments of the invention, prior to the installation of the advertising modules and other system components.

FIG. 4 shows a frame structure according to embodiments of the invention, prior to the installation of the advertising modules and other system components.

FIG. 5 shows a wheel assembly for use with embodiments of the invention.

FIG. 6 shows an analog scrolling display for use with embodiments of the invention.

### DETAILED DESCRIPTION

A mobile advertising and mobility conveyance is disclosed in which one or more types of advertising media may be attached to a powered mobile apparatus that may be operated by a user with a physical disability, limited mobility, limited physical dexterity or motor function, or similar condition. Variants of the conveyance may be adapted for both indoor and outdoor use.

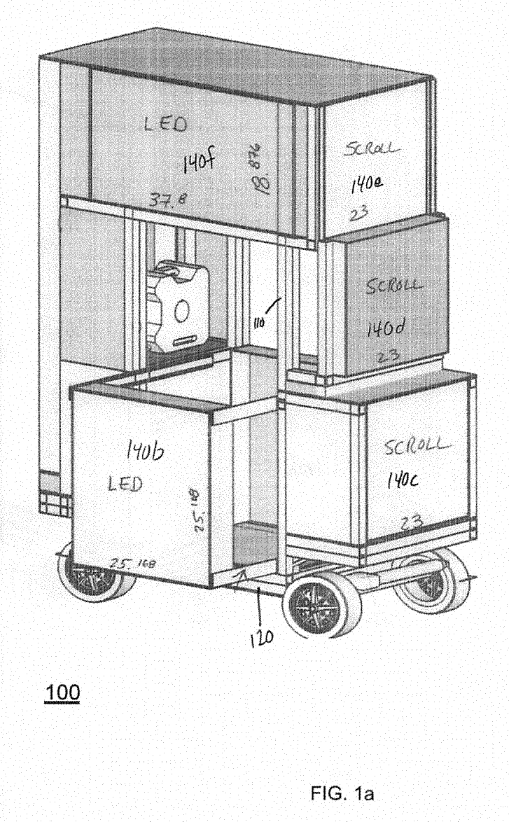

FIGS. 1a-1b a depict a conveyance according to a preferred embodiment of the invention. Conveyance 100 generally comprises a frame portion 110, chassis 120, power supply (obscured in FIGS. 1a-1b, but positioned behind module 140a), and one or more advertising modules 140a-140h.

### Frame

Frame 110 may provide support for the system components and define the overall shape of the conveyance, and comprises multiple connected sections that support the advertising components, power supply, controls, system electronics, and the operator. In embodiments, the frame sits atop, and is supported by, the chassis. In alternate embodiments, the frame and chassis may be integrated into a single unit.

Frame 110 may comprise a network of frame members that interlock or are joined to define individual operator and storage compartment, and supports for individualized advertising modules.

The selection of a particular material or frame member configuration will depend on the intended application of the conveyance, including whether the conveyance is configured for internal or external operation, the number and types of advertising modules, power supply, range, and the like. A conveyance intended to operate outdoors over a limited area may require a material that provides protection to the operator (from impacts and other outdoors hazards), but with less concern for weight. A conveyance having a longer intended operable range may be constructed with a more lightweight material such as titanium. For a conveyance having purely internal operation and limited range—such as a shopping mall or stadium—protection from impact may be less of a concern and a softer, less expensive material such as aluminum may be employed. The selection of frame material may dictate the number and type of advertising modules that can be supported and may be factored into the frame construction. Whether the conveyance will support an operator or be remotely operated may also factor into the frame selection.

With these design considerations in mind, a variety of materials may be used for the frame provided they are sufficiently strong to supports all system components and operator, including, aluminum, steel, titanium, wood, fiberglass, carbon fiber and composite materials, among others.

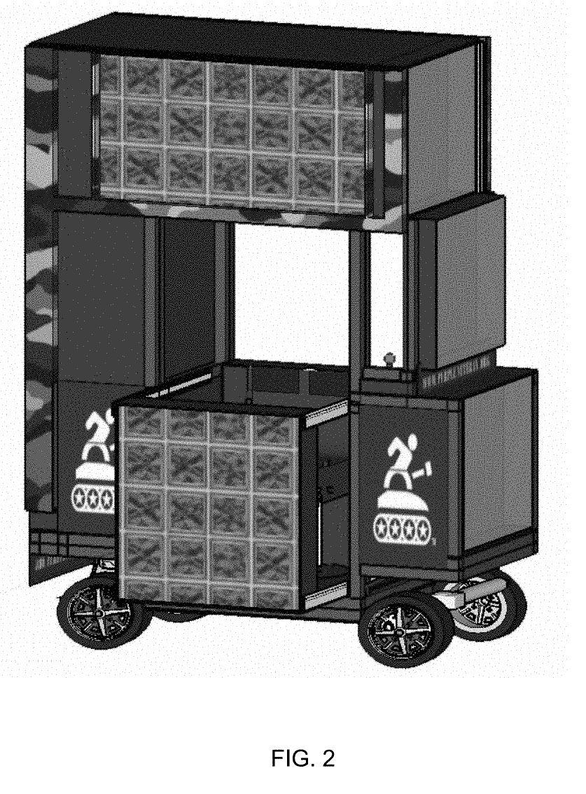

FIG. 3 shows a frame structure 300 according to embodiments of the invention, prior to the installation of the advertising modules and other system components. In embodiments, frame members may define a: (1) support structure and (2) individualized frames to support advertising modules. Frame elements 310a-310d may be joined at the corners to define a module frame 310 that can support an LED panel, scrolling sign, or other advertising element. In the embodiment shown in FIG. 3, the module frame 310 measures approximately 26″ in width and 60″ in height to provide over ten square feet of advertising space. The specific element to be installed in this frame, whether a lightweight analog scrolling sign or stable media versus electronic media—will inform the specific design of the frame.

It should be noted, and will be appreciated by those of ordinary skill in the art, that all dimensions cited herein—whether for the frame or other elements—are merely exemplary, and a conveyance coming within the scope of the invention can be of any shape, size, or aspect ratio limited only by the intended application of the conveyance.

In embodiments, similarly-sized and configured module frames may be positioned at the top left and right sides 330, 334 of the conveyance at a height slightly above eye level for an average pedestrian. Shapes other than rectangular may also be employed for the module frame, such as the square frames 315, 320 shown at the end portions of the conveyance. In embodiments, the module frame alignment may be symmetrical across the conveyance (e.g., in the case of automated or remoted operation), or may be configured to accommodate the physical presence of an operator. In the embodiment of FIG. 3 a space has been left between the vertical position of square module frames 315, 320 to provide a forward view to the operator. Installing a full-length advertising module such as rectangular module frame 310 would obscure the view of an operator sitting in the operator compartment and inhibit the forward movement of the conveyance.

A plurality of frame elements may also be provided to define a support structure. Referring to FIG. 3, vertical supports 350a-350d position advertising modules 320, 330, 334 at approximate eye level, while also defining an operator compartment. Frame elements may also define a compartment housing a power supply 360, and provide lateral support to the overall structure.

In embodiments, a frame, may be fixed or adjustable, with interchangeable modules to customize the advertising components for a particular application. In certain embodiments, frame elements may be movable. A module frame 345 defining an outer wall of the operator compartment may be hingedly connected along a vertical axis to, for example, a vertical support to operate as a door to the operator compartment.

In embodiments, frame elements may be configured to enable advertising modules to move parallel to the ground, or slide along the exterior perpendicular to the ground. For example, frame module 320 is shown in FIG. 3 in alignment with the top of the conveyance. When the conveyance is in a parked state, frame module 320 may be lowered to expose a second module behind frame module 320, and offering additional media space.

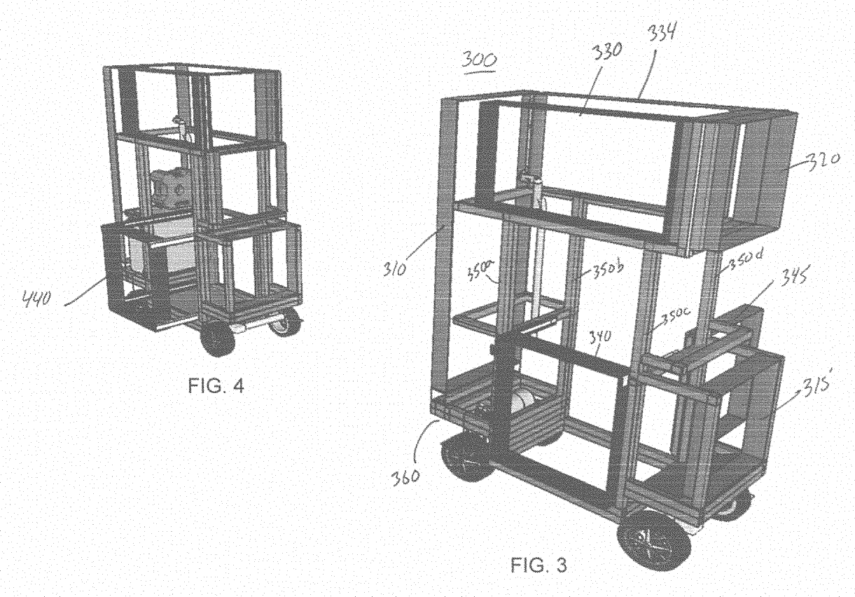

Referring to FIG. 4, each corner of module 440 is connected to a frame element that engages a complementary guide in the operator compartment. In this manner, embodiments of the conveyance may present a sleek footprint to facilitate travel, and expand outward or adjust when stationary.

Sliding may be facilitated through friction or enhanced with ball bearings. Electromechanical components may be used such as an electric linear actuator or other motorized component.

The width of the conveyance may be a design concern in certain environments where lateral space is limited, such as indoor hallways or elevators. The height of the conveyance may similarly be limited where vertical space is limited. Municipalities may be required to make design choices consistent with the Americans With Disabilities Act, Accessible Design and the Uniform Federal Accessibility Standards, or other statutes. While not regulated by these acts directly, and not necessarily classified as a medical device, the conveyance may be designed to fall within the design guidelines put in place under these statutes. For example, curb ramps at pedestrian crossings are common, and variations of the conveyance may need to utilize these curb ramps and the width of the conveyance must be considered against these guidelines.

Rather than an angular exterior, conveyance 300 may take an arcuate appearance, possibility with decorative cladding over the frame. Such cladding may be permanent or removable and modular to permit interchangeable themes.

As shown in FIG. 3, frame 300 defines an operator compartment with a door 345 for access. A storage compartment may be configured above the operator compartment, and behind the advertising modules making up the upper periphery of the conveyance. Assuming a preferred embodiment size of roughly 38″ long, and 26″ wide, a storage compartment extending 19″ above the operator would provide a capacity of over 10 cubic feet, more than ample to transport a wheelchair, personal effects, advertising handouts, or any objects relevant to the operator or mission.

A frame may support additional elements discussed below, including ventilation or an exhaust pipe, a supplemental fuel supply, and operator control, among others. The frame may further support elements to shield the operator from weather or environmental conditions, such as, for example, a windshield, sunscreen, or canopy.

### Chassis

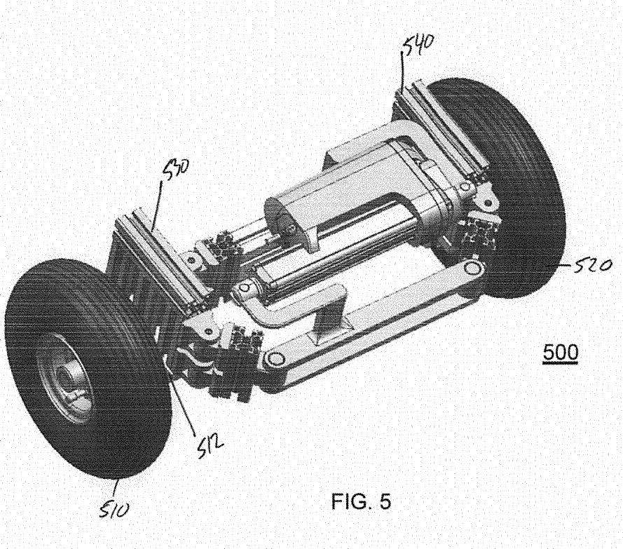

In embodiments, a chassis for supporting the frame comprises a plurality of wheel assemblies joined together by frame elements to provide a moveable base for the remainder of the conveyance, as shown in FIG. 5. Two wheels 510, 520 are attached via axles to a center assembly that provides propulsion and steering for the individual wheel assembly in response to signals from a control panel or control conveyance.

Lateral flange members 530, 540 may connect to the base of the upper frame supporting the remainder of the conveyance. In embodiments, braking may be facilitated within the propulsion system or via discrete braking elements fitted to the wheel assembly. In embodiments, an upper frame may be detachable from the chassis to permit different frame styles to be used with a single chassis, or vice-versa.

Center assembly may further include electronics in communication with an operator console that directs the movement, either propulsion or steering, of individual wheel assemblies.

Wheel assemblies may be provided in pairs—with two sets of wheels each similar to an automobile—or in odd numbers, depending on the configuration and load. In embodiments, all wheel assemblies may be powered or, to reduce cost and weight, only select assemblies may be powered with the remaining assemblies limited to steering and/or support. In embodiments, a suspension system may be incorporated in one or more wheel assemblies to enhance operator comfort and protect electronic components from damage.

In embodiments, the chassis may be further weighted to lower the center of gravity of the conveyance and inhibit toppling.

In embodiments, tires 510, 520 may be pneumatic to provide comfort and impact resistance, and are, preferably, puncture resistant to provide enhanced protection against debris and obstacles in an urban environment. In addition to air-filled pneumatic variants, tires may be solid, or foam-filled run-flat styles. In a prototype embodiment, tires fitting an 8″ rim were utilized for an outdoor environment.

It will be appreciated by those of skill in the art that the greater the wheel diameter, the higher the overall profile of the conveyance, which may be a concern for operating in certain indoor environments. Similarly, wider tires may improve comfort and stability, but limit access to certain environments or necessitate other design changes in the conveyance. As with other system components, the specific wheel and tire size will depend on the intended application.

Advertising modules for use with embodiments of the present invention may take a number of forms including, without limitation, digital signage such as LED and LCD displays, and scrolling programmable LED signs, as well as analog signage such as scrolling displays, printed inserts, lithographic printed billboard-style applications, and the like. In a preferred embodiment, advertising modules may be dynamic and be capable of rapid changes in messaging or programming to adapt to different or changing conditions.

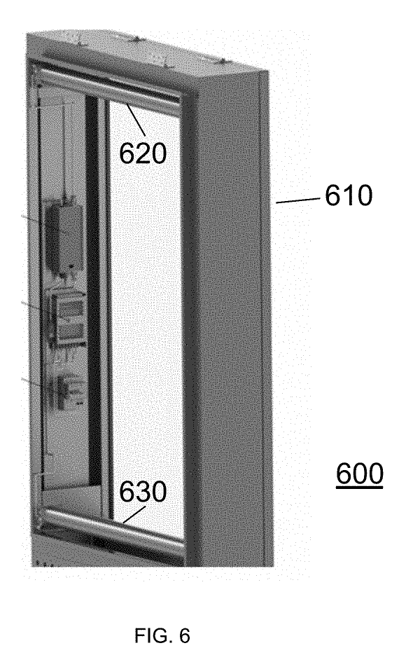

Referring to FIG. 6, an exemplary analog scrolling display is shown. Scrolling system 600 may comprise a frame portion 610 that defines an outer periphery of the display. Rollers 620, 630 may be positioned at opposing ends—along either the horizontal or vertical axes—and be connected at the peripheral edges to frame portion 610 by way of a taper lock bushing or similar component. In embodiments, rollers may be formed from a material with a smooth exterior surface such as PVC, aluminum, stainless steel, or the like. In embodiments, rollers 620, 630 may be a tube or pipe having a diameter sufficient to inhibit bowing or warping under the load.

In a preferred embodiment, rollers 620, 630 may further comprise a clipping portion running along the radial axis of the roller to grasp the end of the advertising media as the media is rolled or unrolled circumferentially about the roller. A motor may be provided within or adjacent each roller to turn the advertising media and advance to the successive advertisement to be displayed. Motor may be connected to a PCB and control conveyance that is managed from a center operator console, or independently. As an alternative to a motor, a hand crank may be employed to advance the advertising medium to the successive message.

In embodiments, advertising media is preferably a durable, lightweight material with moderate tensile strength. In embodiments, the advertising media is substantially translucent to permit backlighting. Examples of suitable advertising media include Mylar, Tyvek, nylon, linen, paper, printed cloth, and PVC, among others.

In embodiments, this type of advertising module may be outfitted with a light source behind the advertising media to provide rear illumination of the advertisement. Light sources may include LED, fluorescent, and incandescent, among others, and be preferably resistant to breakage.

In addition to scrolling display, embodiments of the invention may use one or more LED panels to provide a full-color, programmable, dynamic display to engage an audience. Referring to FIG. 1a, example LED panels are shown in dimension of 37.8×18.876 and 25.168×25.168, though any size, shape or aspect ratio may be utilized, limited only by the size and configuration of the overall conveyance.

The precise specifications for a given panel may depend on the intended use, including whether the conveyance will operate outdoors or indoors or both, and if exposed to an outdoor environment, the conditions that may be encountered such as temperature, heat, humidity, precipitation, and sunlight. An additional consideration for selection of an LED panel may be the expected or average viewing distance, and also the viewing angle.

As with other types of displays LED panels comprise a plurality of individual pixels, each of which contain a red diode, a blue diode, and a greed diode. The diodes are selectively illuminated to form an image on the screen. The sharpness of a given LED panel may be measured by the density of the pixels, one measure of which is the “P” rating. The “P” rating provides the distance from the center of a pixel to the adjacent pixel(s), measure in millimeters. Accordingly, a panel rated as P10 would have pixels spaced at 10 mm intervals, regardless of the overall size of the display. A P6 panel would have pixels spaced at 6 mm intervals; P4 at 4 mm intervals, and P0.5 at 0.5 mm intervals.

In addition to sharpness, pixel density or “P” rating may impact the minimum and preferred viewing distances, all of which may be factored in to the selection of a panel.

It has been found that an LED panel rated at, preferably no higher than P5 is suitable for a typical use case of embodiments of the invention and provides a balance between resolution and quality, price, weight, and power consumption. A P5 LED Panel would have an optimal minimum viewing distance of 5 m, and a preferred viewing distance of 9.0 m. LED panels of increasing density, down to even as low as P0.5—comparable to home HDTV quality—and beyond may be employed, the determining factor being the expected distance between the conveyance and the viewing public. Dense urban areas and crowded indoor areas and may require a denser display since viewer engagement would be expected to be closer.

Small and large video display installations have become a popular means for engaging the public, and may be found at stadiums, airports, train stations, building lobbies, and the like. The growth of these installations has reduced the price of the panels and led to a vast market for these panels. The particular brand of panel has been found to be less material than the specifications for the panel.

In embodiments, LED panels may be modular, enabling the replacement of a damaged panel can be replaced without taking the entire conveyance out of service. In embodiments, LED panels may connect to a central control that coordinates the content of the individual displays. In embodiments, a light sensor may be utilized to detect the level of ambient display and adjust the brightness of the display to the optimum for the conditions. Additional sensors may be used to detect temperature, humidity, presence of moisture and the like, and adjust the LED panels to provide optimum viewing or simply to protect the integrity of the conveyance.

As an alternative to LED panels, an HDTV display may be utilized. HDTV display—such as LED LCD displays—tend to have higher resolution and pixel density than LED panels, but also have a higher cost, greater weight, and greater power consumption. Nevertheless, these displays may be preferable in certain operating environments, particularly where a very sharp display is desirable.

In embodiments, a light sensor may work with a control system to determine whether the level of ambient light warrants additional illumination in the form of backlighting (scrolling signs), brightness (LED/LCD), or otherwise.

In embodiments, advertising modules may also comprise one or more scrolling LED signs. These signs tend to have very low pixel density, making them suitable for advertising content comprising text only or simple graphics, optionally in varying colors. Many of these signs come outfitted with a controller system that facilitates entry of text, and enables display features such as scrolling, flashing, and other effects. Scrolling LED signs may be integrated into the overall control system of the conveyance. In simpler versions of the invention, scrolling LED signs with an embedded controller may be utilized to provide a turnkey installation.

The foregoing examples of advertising modules are exemplary, and it will be appreciated by those of skill in the art that a wide variety of advertising media can be employed with the present invention.

In embodiments, the system will have a power source capable of powering the movement of the conveyance, and also the various electrical and electronic components affixed to the frame.

In a preferred embodiment, one or more rechargeable lithium ion batteries may be used. Lithium ion batteries are well-suited for embodiments of the invention because of their light weight, compactness, and long cycle life. In embodiments, one or more lithium ion batteries may be installed, for example, adjacent the operator compartment shown in FIGS. 1a-1b. An electronic control system may provide data to such as remaining charge, time or distance to empty, time to charge, which may be visualized on an operator control panel.

At present, lithium ion batteries are considerably more expensive than other power sources, which may make them less desirable until the costs decreases. Various power options are available as alternatives. For example, a lead acid battery may be utilized to power embodiments of the invention.

In embodiments of the invention that are solely for outdoor use, a portable electric generator may be used. A Honda EU2000 generator was used with prototype embodiments of the invention. This generator—and those having similar specifications—provides stable power up to 2000 watts, sufficient for configurations of the invention. Importantly, this particular generator is relatively lightweight and operates at 53 to 59 dBA, making it comparatively quiet. In embodiments, a generator compartment on the conveyance may be design to mitigate the sounds of the generator. Noisier generators may be off-putting and unwelcome in certain outdoor environments.

Since any gasoline-powered generator requires an exhaust port, embodiments of the invention may be outfitted with a hose or pipe that attaches to the generator and delivers the exhaust above or adjacent the conveyance. FIG. 3 shows such an exhaust pipe. Additionally, a supplemental fuel supply may be provided to augment the small (often less than one gallon) fuel tank of the generator.

In embodiments, other power sources may be utilized, separately or in tandem with other sources. For example, hybrid vehicle technology may be utilized with embodiments of the invention to supplement a generator. Solar power may be employed to provide power to the conveyance.

A control panel, may be provided to enable the user to control both the advertising messaging and the movement and steering of the conveyance.

In a preferred embodiment, control panel may be outfitted with a joystick for controlling forward and rear propulsion, braking and also steering of the conveyance. In a preferred embodiment, the primary propulsion and steering control should be operable by persons with limited physical dexterity or hand function. Alternatives include handlebars, a traditional steering wheel, or touchpad, among others. Steering and braking function may be mechanical, hydraulic, or purely electronic.

In embodiments, a visual display may be integrated into the conveyance and may incorporate a touchscreen to interact with the system. In addition to movement, visual display may permit control over the plurality of advertising modules installed on the conveyance.

In embodiments, the conveyance may connect with a mobile computing device such as a tablet computer, to receive instruction concerning the content and timing of advertising, and even the movement of the conveyance. In embodiments, conveyance may be in wireless communication with a remote computing device that controls the content and timing of advertising, and even the movement of the conveyance.

In embodiments, advertising content may be under the control of the operator and pre-loaded prior to deployment, or may be dynamically loaded, possibly in response to the location of the conveyance, or other conditions. Advertising content, whether pre-loaded or dynamic, may be programmed to adapt to conditions such as the time of day, location, or proximity to specific individuals.

As discussed above, in embodiments of the invention, the conveyance itself may be configured to accommodate persons having physical limitations, and the unit is designed with the disabled in mind. It is steered using a joystick, has wheelchair storage compartment overhead, all dials/attachments/maintenance can be handled, seating is designed for easy access (not shown). The conveyance may also be configured to comply to federal, state, and municipal regulations to ensure access to particular pedestrian-rich environments, though not necessarily bound federal, state, or municipal laws concerning access for the disabled. This is an optional design consideration, and one of several variations of the conveyance of the present invention.

It will be understood that there are numerous modifications of the illustrated embodiments described above which will be readily apparent to one skilled in the art, including any combinations of features disclosed herein that are individually disclosed or claimed herein, explicitly including additional combinations of such features. These modifications and/or combinations fall within the art to which this invention relates and are intended to be within the scope of the claims, which follow. It is noted, as is conventional, the use of a singular element in a claim is intended to cover one or more of such an element.

1. A mobile media conveyance comprising:
a plurality of frame segments defining a support structure, and at least one media frame;
a chassis connected to the support structure comprising a moveable platform, and one or more wheel assemblies;
a control panel comprising a control mechanism adapted to receive input from a user present in the conveyance for directing the movement and direction of the mobile media conveyance;
at least one media module in the at least one media frame;
a mobile power source configured to provide power to the one or more wheel assemblies to drive the movement of the conveyance; and
wherein the at least one media module is configured to provide content in response to operator input; and
wherein an operator compartment is defined by the plurality of frame segments and at least one media frame.

2. The mobile media conveyance of claim 1 wherein the content is dynamic.

3. The mobile media conveyance of claim 1 wherein the at least one of the media frame is horizontally or vertically slideable such that the interior volume of the operator compartment changes in volume.

4. The mobile media conveyance of claim 1 wherein a connection between the chassis and the support structure is removable.

5. The mobile media conveyance of claim 1 wherein the at least one media module is one of: a light emitting diode display; a liquid crystal display; a fixed display; and a scrolling analog display.

6. The mobile media conveyance of claim 1 wherein the content is adjusted based upon the location of the conveyance.

7. The mobile media conveyance of claim 1 wherein the control panel receives direction from an operate in a remote location.

8. The mobile media conveyance of claim 1 wherein the mobile media conveyance is sized in accordance with governmental regulations for the disabled.

9. The mobile media conveyance of claim 1 wherein the power source is a rechargeable lithium ion battery array.

10. (canceled)

11. (canceled)

12. (canceled)

13. (canceled)

14. (canceled)

15. (canceled)

16. (canceled)

17. A mobile media conveyance comprising
a plurality of frame segments defining a support structure, a storage compartment, and at least one media frame;
a chassis connected to the support structure comprising a moveable platform, and one or more wheel assemblies;
a control panel comprising a control mechanism adapted to receive input from a user present in the mobile media conveyance for directing the movement and direction of the mobile media conveyance;
at least one media module in the at least one media frame;
a mobile power source configured to provide power to the one or more wheel assemblies to drive the movement of the conveyance;
wherein the at least one media module is configured to provide content in response to operator input;
wherein an operator compartment is defined by the plurality of frame segments and at least one media frame; and
wherein the storage compartment is configured to receive a personal mobility device such as a wheelchair.
